(19) United States
(12) Patent Application Publication
(10) Pub. No.: US 2016/0078931 A1
(43) Pub. Date: Mar. 17, 2016

(54) MEMORY DEVICE AND METHOD FOR MANUFACTURING THE SAME

(71) Applicant: Kabushiki Kaisha Toshiba, Minato-ku (JP)

(72) Inventor: Kiyohito NISHIHARA, Yokkaichi (JP)

(73) Assignee: Kabushiki Kaisha Toshiba, Minato-ku (JP)

(21) Appl. No.: 14/615,802

(22) Filed: Feb. 6, 2015

Related U.S. Application Data
(60) Provisional application No. 62/049,202, filed on Sep. 11, 2014.

(51) Int. Cl. G11C 13/00; H01L 45/00

(52) U.S. Cl. CPC G11C 13/0002; H01L 45/16

(57) ABSTRACT

According to one embodiment, a memory device includes a first wiring line extending in a first direction, a second wiring line extending in a first direction, the first wiring line and the second wiring line being separated from each other, a third wiring line separated from the first wiring line and the second wiring line, at least one portion of the third wiring line extending in a second direction crossing the first direction, a fourth wiring line separated from the first wiring line and the second wiring line, at least one portion of the fourth wiring line extending in the second direction, a first interconnect connected between a side surface of the first wiring line and a side surface of the third wiring line, and a second interconnect connected between a side surface of the second wiring line and a side surface of fourth wiring line.

### CROSS-REFERENCE TO RELATED APPLICATIONS

This application is based upon and claims the benefit of priority from U.S. Provisional Patent Application 62/049,202, filed on Sep. 11, 2014; the entire contents of which are incorporated herein by reference.

### FIELD

Embodiments described herein relate generally to a memory device and a method for manufacturing the same.

### BACKGROUND

In recent years, a resistance random access memory device has been proposed in which data is stored by utilizing the change of an electrical resistance value of a variable resistance film. To efficiently integrate the memory cells, a cross-point structure in which the memory cells are connected between word lines and bit lines has been proposed as the device structure of such a resistance random access memory device. When commercializing the resistance random access memory device having the cross-point structure, it is desirable to improve the patternability.

### BRIEF DESCRIPTION OF THE DRAWINGS

FIG. 1 is a plan view showing a memory device according to an embodiment;

FIG. 2 is a perspective view showing a memory unit and a bit line contact region of the memory device according to the embodiment;

FIG. 3 is a plan view showing the memory unit of the memory device according to the embodiment and periphery of the memory unit;

FIG. 4A is an enlarged view of portion A shown in FIG. 3; and FIG. 4B is a cross-sectional view along line B-B′ shown in FIG. 4A;

FIG. 5A is a plan view of the bit line contact region showing a manufacturing process of the memory device according to the embodiment; and FIG. 5B is a cross-sectional view along line C-C′ shown in FIG. 5A;

FIG. 6A is a plan view of the bit line contact region showing a manufacturing process of the memory device according to the embodiment; and FIG. 6B is a cross-sectional view along line D-D′ shown in FIG. 6A;

FIG. 7A is a plan view of the bit line contact region showing a manufacturing process of the memory device according to the embodiment; and FIG. 7B is a cross-sectional view along line E-E′ shown in FIG. 7A;

FIG. 8A is a plan view of the bit line contact region showing a manufacturing process of the memory device according to the embodiment; and FIG. 8B is a cross-sectional view along line F-F′ shown in FIG. 8A;

FIG. 9A is a plan view of the bit line contact region showing a manufacturing process of the memory device according to the embodiment; and FIG. 9B is a cross-sectional view along line G-G′ shown in FIG. 9A;

FIG. 10A is a plan view of the bit line contact region showing a manufacturing process of the memory device according to the embodiment; and FIG. 10B is a cross-sectional view along line H-H′ shown in FIG. 10A;

FIG. 11A is a plan view of the bit line contact region showing a manufacturing process of the memory device according to the embodiment; and FIG. 11B is a cross-sectional view along line I-I′ shown in FIG. 11A;

FIG. 12A is a plan view of the bit line contact region showing a manufacturing process of the memory device according to the embodiment; and FIG. 12B is a cross-sectional view along line J-J′ shown in FIG. 12A; and

FIG. 13A and FIG. 13B are plan views of the bit line contact region showing a manufacturing process of the memory device according to a modification of the embodiment.

### DETAILED DESCRIPTION

In general, according to one embodiment, a memory device includes a first wiring line extending in a first direction, a second wiring line extending in a first direction, the first wiring line and the second wiring line being separated from each other, a third wiring line separated from the first wiring line and the second wiring line, at least one portion of the third wiring line extending in a second direction crossing the first direction, a fourth wiring line separated from the first wiring line and the second wiring line, at least one portion of the fourth wiring line extending in the second direction, a first interconnect connected between a side surface of the first wiring line and a side surface of the third wiring line, and a second interconnect connected between a side surface of the second wiring line and a side surface of the fourth wiring line.

Embodiments of the invention will now be described with reference to the drawings.

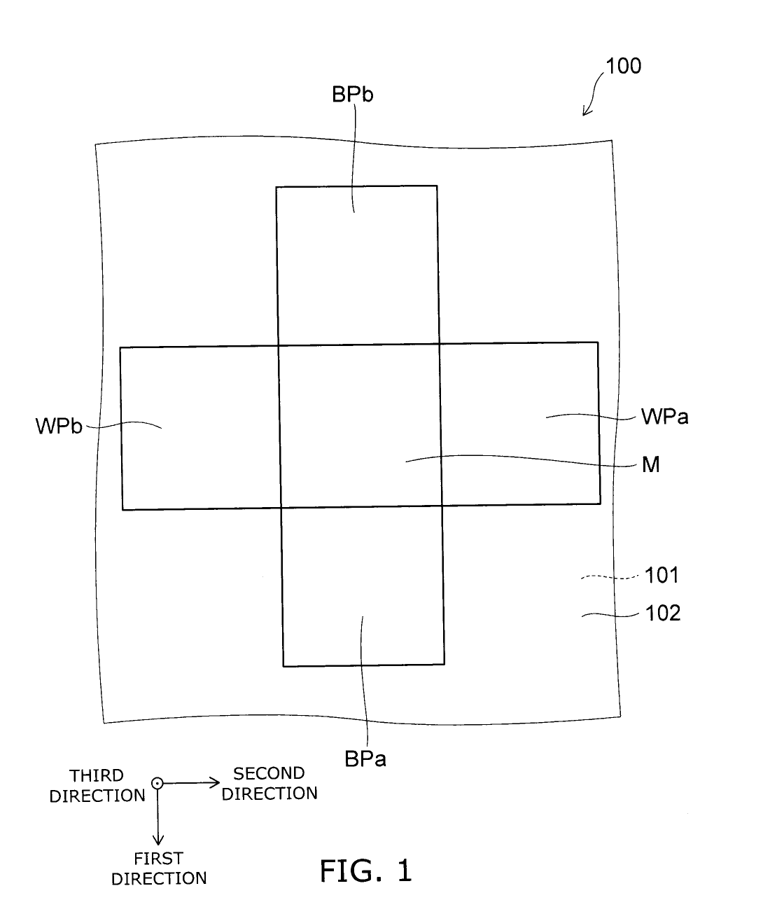

FIG. 1 is a plan view showing a memory device according to the embodiment.

As shown in FIG. 1, a silicon substrate 101 is provided in the memory device 100 according to the embodiment; and a drive circuit (not shown) of the memory device 100 is formed in the upper layer portion and on the upper surface of the silicon substrate 101. An inter-layer insulating film 102 is provided on the silicon substrate 101 to bury the drive circuit.

For convenience of description hereinbelow, two mutually-orthogonal directions parallel to the upper surface of the silicon substrate 101 are taken as a “first direction” and a “second direction”; and a direction perpendicular to the upper surface of the silicon substrate 101 is taken as a “third direction”.

When viewed from the third direction, for example, a square memory unit M is provided on the silicon substrate 101; bit line contact regions BPa and BPb are provided at two locations on two first-direction sides as viewed from the memory unit M; and word line contact regions WPa and WPb are provided at two locations on two second-direction sides as viewed from the memory unit M.

First, the configuration of the memory unit M will now be described.

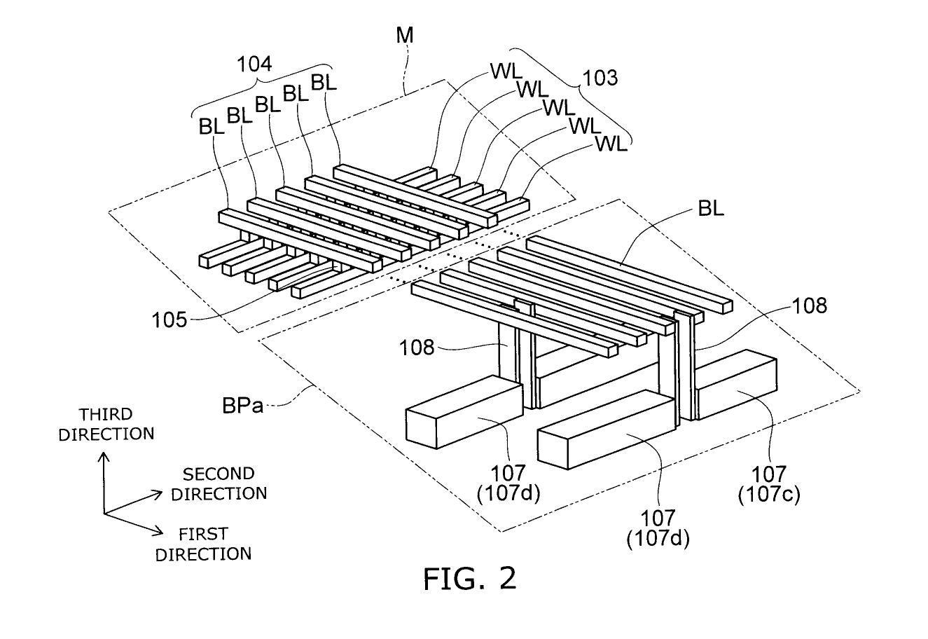

FIG. 2 is a perspective view showing the memory unit M and the bit line contact region BPa.

In the memory unit M of the memory device 100 as shown in FIG. 2, a word line layer 103 that includes multiple word lines WL extending in the second direction is provided; and a bit line layer 104 that includes multiple bit lines BL extending in the first direction is provided on the word line layer 103.

Also, a pillar 105 that extends in the third direction is provided at the most far point between each of the word lines WL and each of the bit lines BL. The pillar 105 is connected between the word line WL and the bit line BL. A variable resistance film (not shown) such as, for example, a metal oxide film, a stacked film of a metal layer, e.g., Cu, Ag, Ni, Ti, or Al, and a silicon layer, etc., is provided in the pillar 105. Thereby, the pillar 105 functions as a resistance random access memory element; and one memory cell includes one pillar 105.

Thus, the memory device 100 is a cross-point device in which memory cells are disposed at each of the most far points between the word lines WL and the bit lines BL. The space between the word lines WL, the bit lines BL, and the pillars 105 is filled with an insulating film (not shown).

The relationship between the memory unit M, the contact regions WPa and WPb, and the bit line contact regions BPa and BPb will now be described.

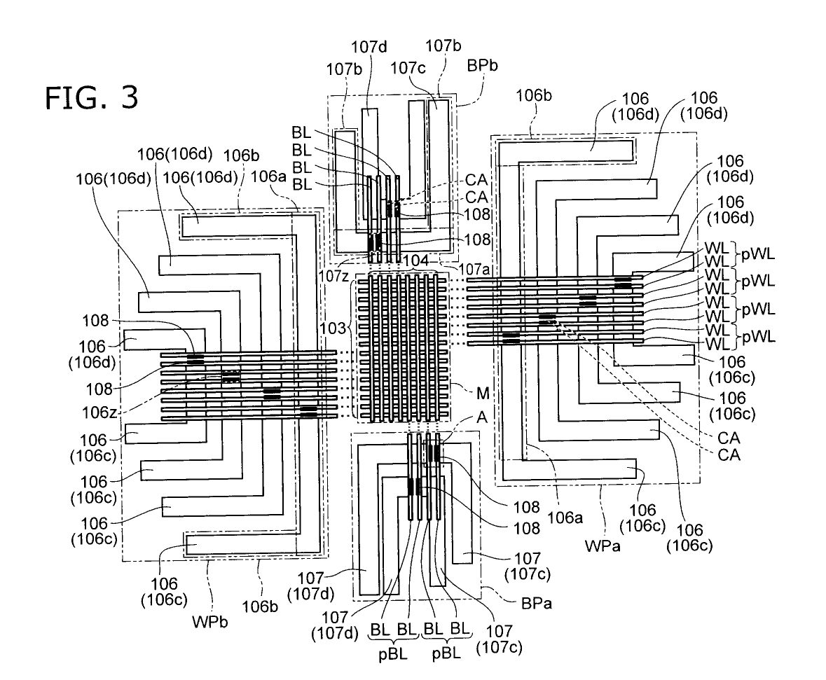

FIG. 3 is a plan view showing the memory unit M of the memory device according to the embodiment and the periphery of the memory unit M.

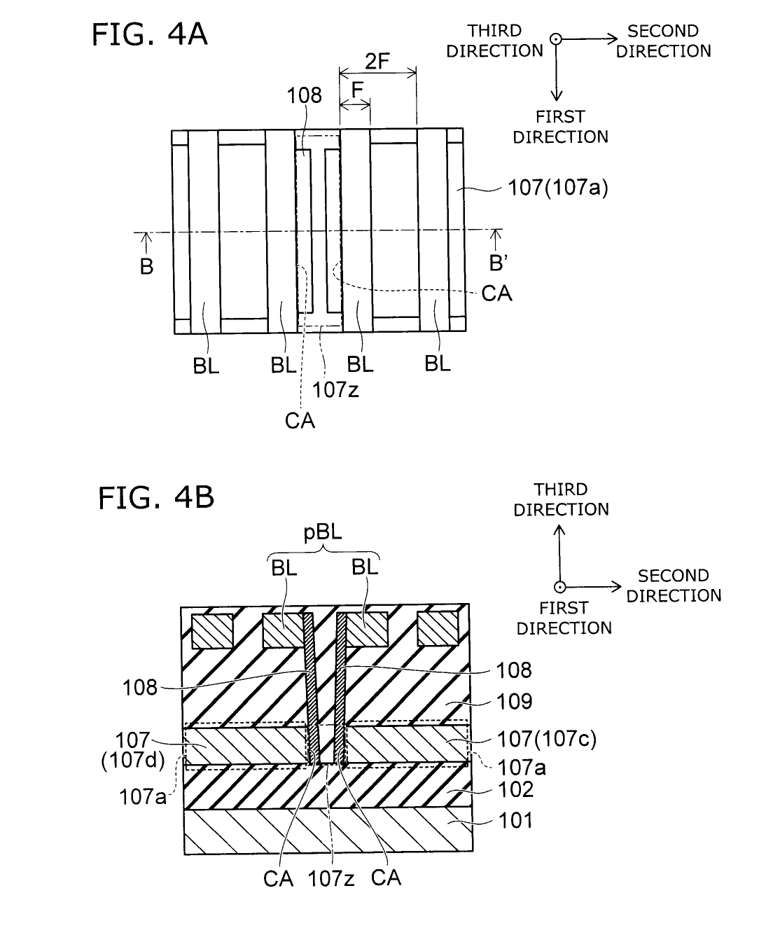

FIG. 4A is an enlarged view of portion A shown in FIG. 3; and FIG. 4B is a cross-sectional view along line B-B′ shown in FIG. 4A.

As shown in FIG. 3, when viewed from the third direction, the bit line contact regions BPa and BPb are provided at two locations on the two first-direction sides of the memory unit M; and the word line contact regions WPa and WPb are provided at two locations on the two second-direction sides as viewed from the memory unit M.

The word lines WL that are provided in the word line layer 103 of the memory unit M are drawn out toward the word line contact regions WPa and WPb. The word line WL is drawn out to one of the word line contact regions WPa or WPb of the two locations.

For example, sixteen word lines WL are provided in the memory unit M and separated from each other along the second direction. Among the sixteen word lines WL, a first group including eight word lines WL consecutively arranged is drawn out to the word line contact region WPa. The eight word lines WL of the first group consecutively arranged are not drawn out to the word line contact region WPb. On the other hand, a second group made of eight word lines WL consecutively arranged is drawn out to the word line contact region WPb. The eight word lines WL of the second group are not drawn out to the word line contact region WPa.

Similarly, the bit lines BL that are provided in the bit line layer 104 of the memory unit M are drawn out toward the bit line contact regions BPa and BPb disposed at the two locations on the two sides in the first direction. The bit line BL is drawn out to one of the bit line contact regions BPa or BPb of the two locations.

For example, eight bit lines BL are provided in the memory unit M and separated from each other along the first direction. A third group of the eight bit lines BL made of four bit lines BL consecutively arranged is drawn out to the bit line contact region BPa. The four bit lines BL of the third group consecutively arranged are not drawn out to the bit line contact region BPb. On the other hand, a fourth group made of four bit lines BL consecutively arranged is drawn out to the bit line contact region BPb. The four bit lines BL of the fourth group are not drawn out to the bit line contact region BPa.

Also, a connecting member wiring line layer that includes multiple word line connecting members 106 and bit line connecting members 107 is provided between the silicon substrate 101 and the bit line layer 104.

In the word line contact regions WPa and WPb, the word line connecting members 106 are provided below the word lines WL drawn out from the word line layer 103. One word line connecting member 106 is U-shaped. One crossing portion 106a and two wiring portions 106b are provided in each of the word line connecting members 106. The crossing portion 106a extends in the first direction and passes through the regions directly under the multiple word lines WL. Thereby, when viewed from the third direction, the crossing portion 106a crosses the multiple word lines WL. The two wiring portions 106b are drawn out respectively from the two end portions of the crossing portion 106a and extend in the second direction away from the memory unit M. The length in the first direction of the crossing portion 106a is shorter away from the memory unit M for the multiple word line connecting members 106. Thereby, the word line connecting members 106 which are far to the memory unit M are formed around the word line connecting members 106 which are near to the memory unit M in three directions.

Each of the crossing portions 106a is cut at one location. Thereby, a pair of mutually-opposed cross-sections CA is formed in each of the crossing portions 106a. At this time, the distance between the opposed side surfaces of the crossing portions 106a is not more than the shortest distance between the two word lines WL in the region directly above. For convenience hereinbelow, the space interposed between the pair of cross-sections CA where the word line connecting member 106 does not exist is called a “cut portion 106z” of the word line connecting member 106. The distance between the opposed side surfaces means the distance between one cross-section CA and the other cross-section CA of the pair of cross-sections CA.

The cut portion 106z is positioned in the region directly under the space between two mutually-adjacent word lines WL. When organizing all of the word lines WL drawn out to the word line contact region WPa into multiple sets pWL for every two mutually-adjacent word lines WL, the sets pWL and the cut portions 106z correspond one-to-one. In other words, the cut portion 106z of one word line connecting member 106 is disposed in the region directly under the space between the two word lines WL belonging to one set pWL. Then, the cut end portions of the word line connecting member 106 are disposed in the region directly under the space between the two mutually-adjacent word lines WL.

The word line connecting members 106 are disconnected. The word line connecting members 106 include word line one-side connecting members 106c and word line one-side connecting members 106d. The word line one-side connecting members 106c are one side of the word line connecting members 106 which were disconnected. The word line one-side connecting members 106d are the other side of the word line connecting members 106 which were disconnected. The word line one-side connecting members 106c are formed on the bit line contact region BPa side as viewed from the third direction. The word line one-side connecting members 106d are formed on the bit line contact region BPb side as viewed from the third direction.

The cut end portions of the word line one-side connecting members 106c are connected to the word lines WL in the regions directly above the end portions by vias (interconnects) 108. The word line one-side connecting members 106d are connected to the word lines WL in the regions directly above the end portions by vias 108. Thereby, one word line connecting member 106 is connected to two word lines WL by two vias 108.

In the bit line contact regions BPa and BPb, the bit line connecting members 107 are provided below the bit lines BL drawn out from the bit line layer 104. One bit line connecting member 107 is U-shaped. One crossing portion 107a and two wiring portions 107b are provided in each of the bit line connecting members 107. The crossing portion 107a extends in the second direction and passes through the regions directly under the multiple bit lines BL. Thereby, when viewed from the third direction, the crossing portion 107a crosses the multiple bit lines BL. The two wiring portions 107b are drawn out respectively from the two end portions of the crossing portion 107a and extend in the first direction away from the memory unit M. The length in the second direction of the crossing portion 107a is shorter away from the memory unit M for the multiple bit line connecting members 107. Thereby, the bit line connecting members 107 which are far to the memory unit M are formed around the bit line connecting members 107 which are near to the memory unit M in three directions.

As shown in FIG. 4A, each of the crossing portions 107a is cut at one location. Thereby, a pair of the mutually-opposed cross-sections CA is formed in each of the crossing portions 107a. Also, as shown in FIG. 4B, the distance between the opposed side surfaces of each of the crossing portions 107a is not more than the shortest distance between the two bit lines BL in the region directly above. For convenience hereinbelow, the space interposed between the pair of cross-sections CA where the bit line connecting member 107 does not exist is called a “cut portion 107z” of the bit line connecting member 107.

The cut portion 107z is positioned in the region directly under the space between two mutually-adjacent bit lines BL. As shown in FIG. 3, when all of the bit lines BL drawn out to the bit line contact region BPa are organized into multiple sets pBL for every two mutually-adjacent bit lines BL, the sets pBL and the cut portions 107z correspond one-to-one. In other words, the cut portion 107z of one bit line connecting member 107 is disposed in the region directly under the space between the two bit lines BL belonging to one set pBL. Then, the cut end portions of the bit line connecting member 107 are disposed in the region directly under the space between the two mutually-adjacent bit lines BL.

The bit line connecting members 107 are disconnected. The bit line connecting members 107 include bit line one-side connecting members 107c and bit line one-side connecting members 107d. The bit line one-side connecting members 107c are formed on the word line contact region WPa side as viewed from the third direction. The bit line one-side connecting members 107d are formed on the word line contact region WPb side as viewed from the third direction.

The cut end portions of the bit line one-side connecting members 107c are connected to the bit lines BL in the regions directly above the end portions by vias 108. The bit line one-side connecting members 107d are connected to the bit lines BL in the regions directly above the end portions by vias 108. Thereby, one bit line connecting member 107 is connected to two bit lines BL by two vias 108.

The relationship between the memory unit and the bit line contact region will now be described.

Although the bit line contact region BPa is described as an example, the configuration of the bit line contact region BPb also is similar.

In FIG. 2, the bit line contact region BPb and the bit lines BL drawn out to the bit line contact region BPb are not shown to simplify the drawing. Also, the word line contact regions WPa and WPb and the word lines WL drawn out to the word line contact regions WPa and WPb are not shown.

As shown in FIG. 2, FIG. 4A, and FIG. 4B, in the memory device 100, the bit lines BL that are provided in the bit line layer 104 of the memory unit M are drawn out to the bit line contact region BPa. In the case where the width of the bit lines BL is set to a minimum patterning dimension F, the bit lines BL are drawn out to the bit line contact region BPa so that the period of the bit lines BL is 2F. Here, the period is the minimum repeated length of the pattern that is repeated periodically.

A method for manufacturing the memory device according to the embodiment will now be described.

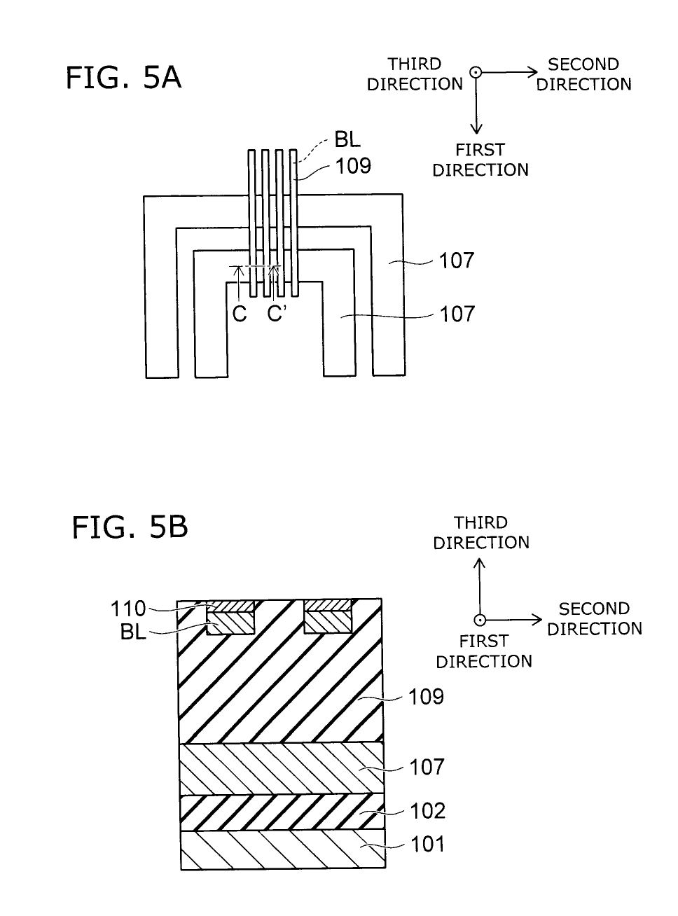

FIG. 5A is a plan view of the bit line contact region showing a manufacturing process of the memory device according to the embodiment; and FIG. 5B is a cross-sectional view along line C-C′ shown in FIG. 5A.

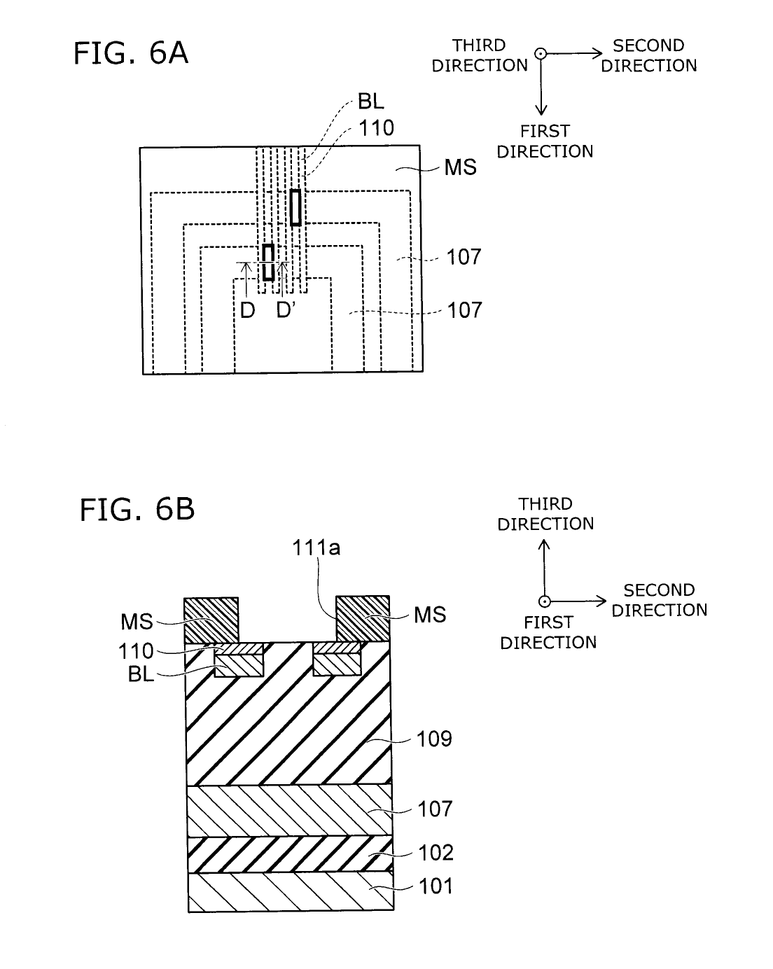

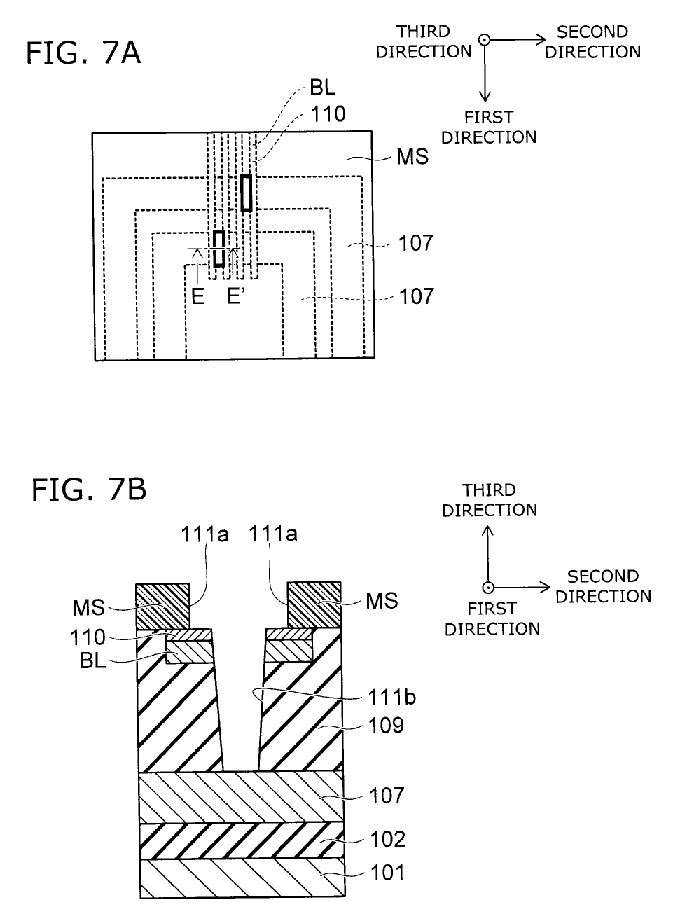

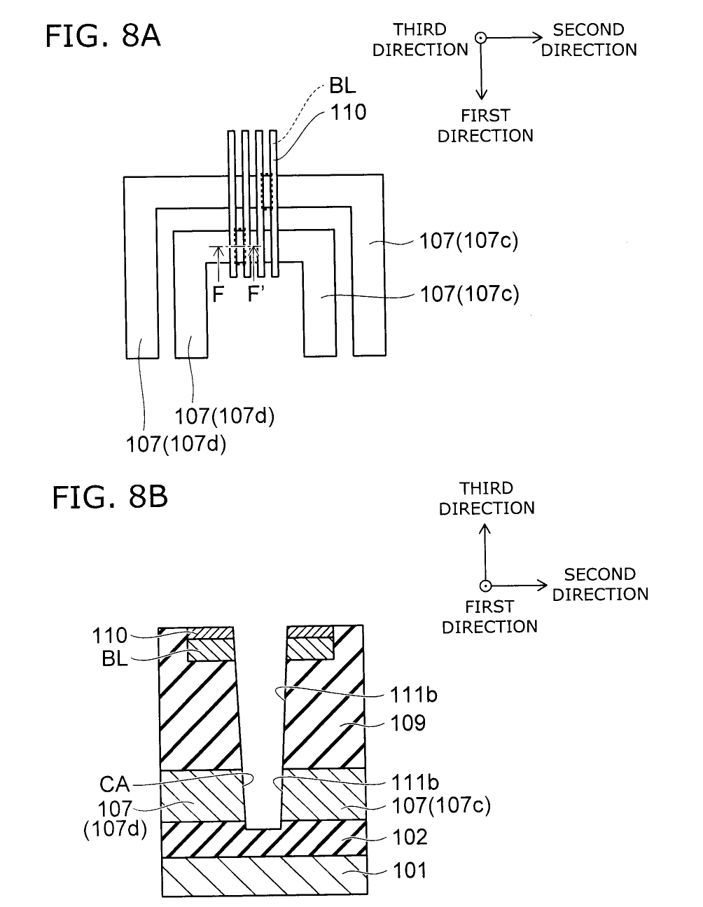

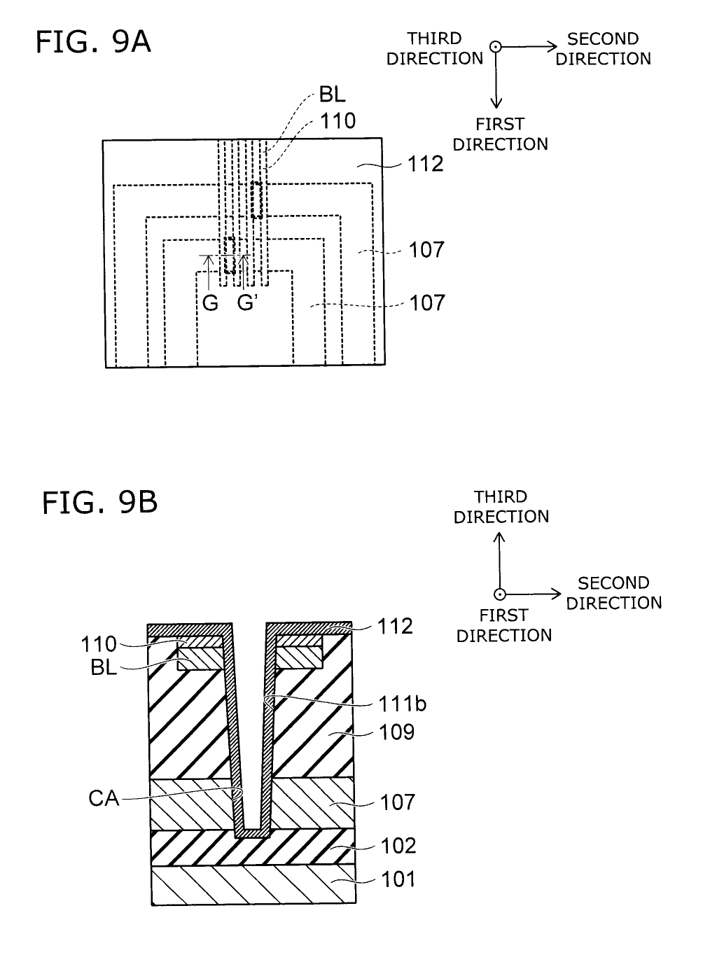

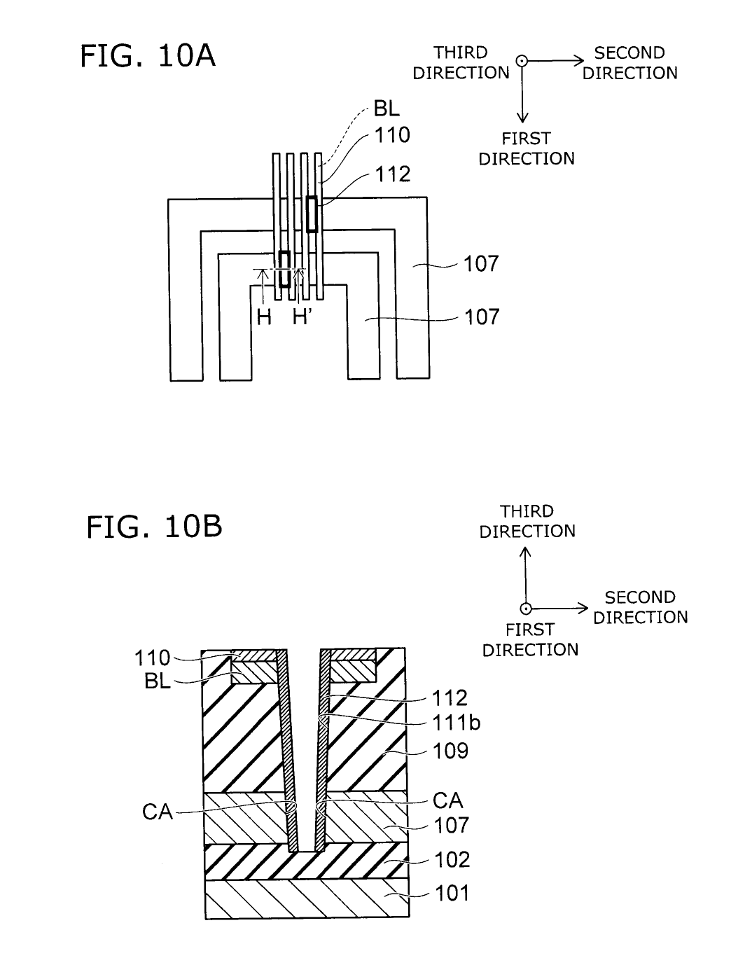

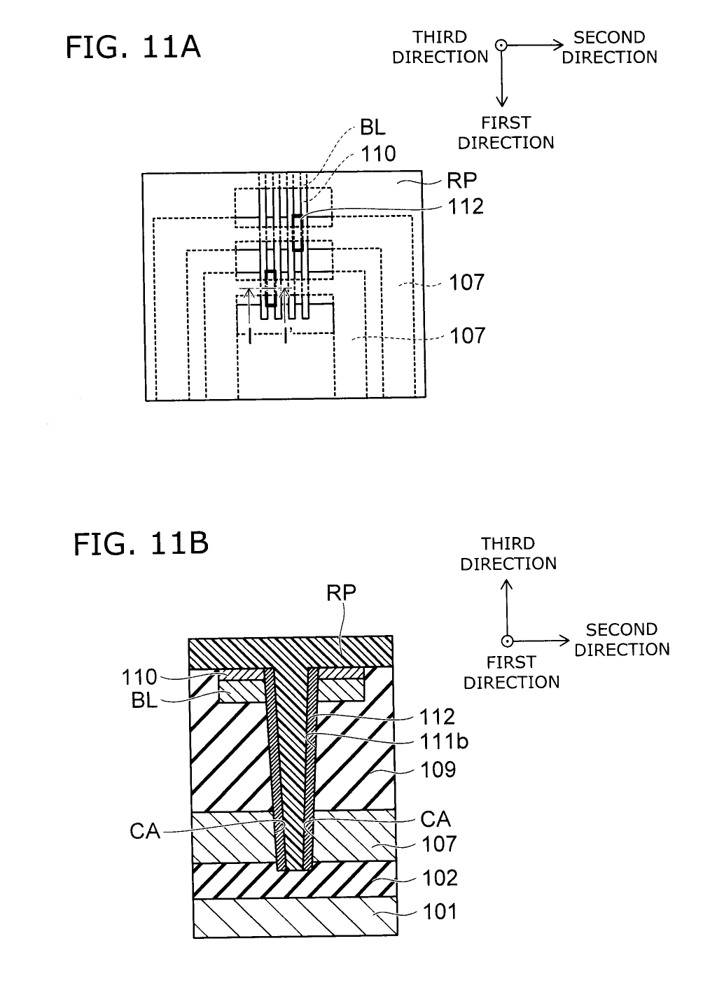

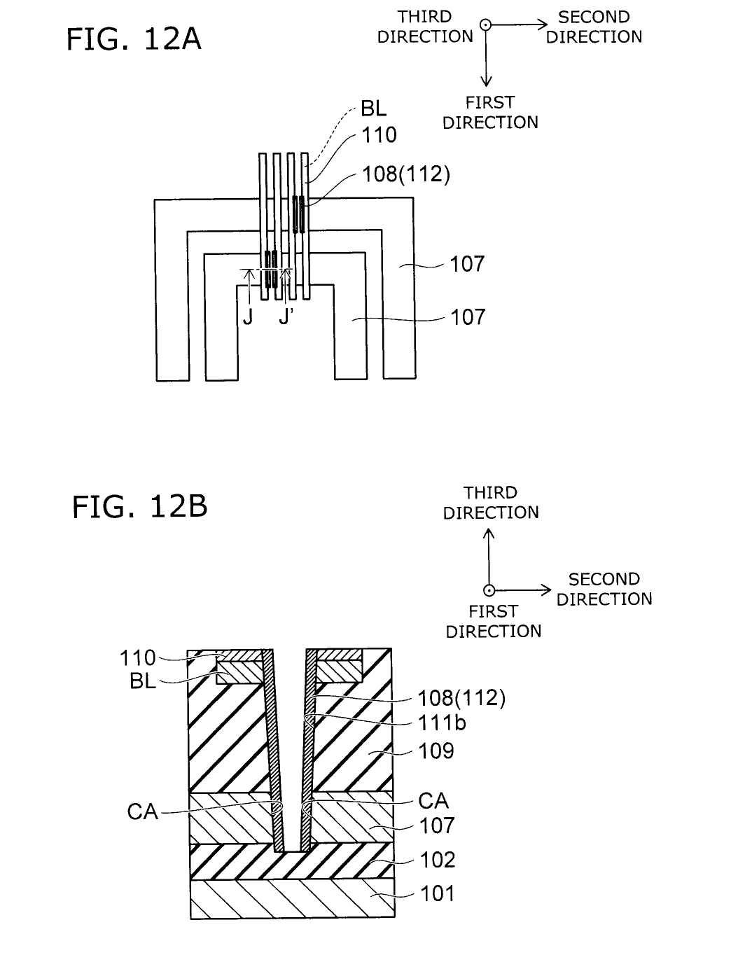

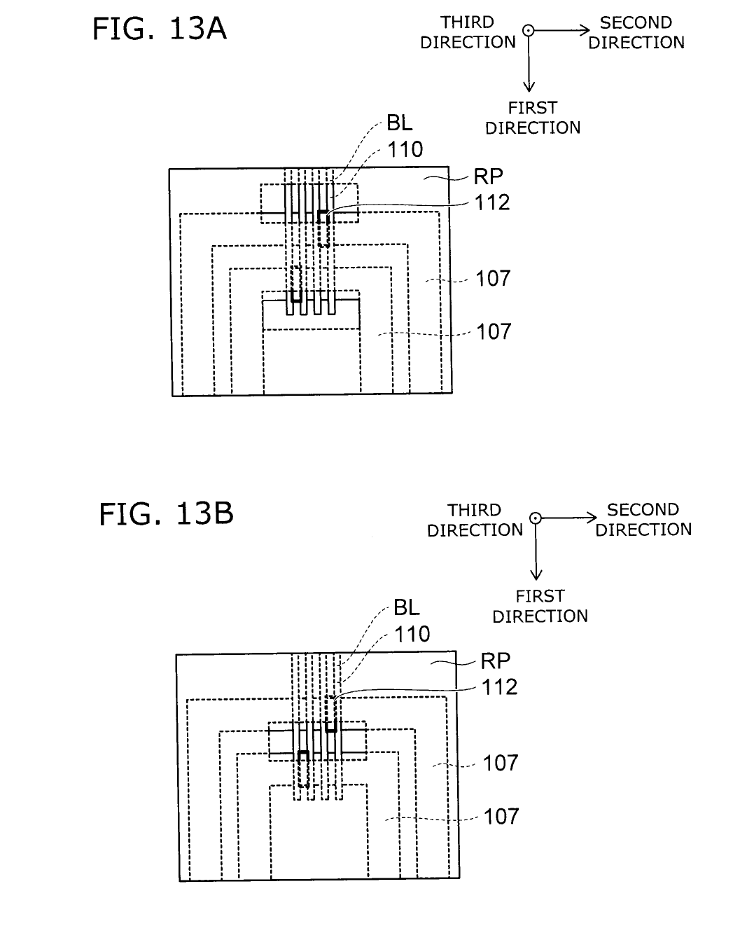

Although the bit line contact region BPa is described as an example hereinbelow, the manufacturing method is similar for the bit line contact region BPb as well. Also, the manufacturing method is similar for the word line contact regions WPa and WPb as well. Also, the silicon substrate 101, the inter-layer insulating film 102, and an insulating film 109 are not shown in FIG. 5A, FIG. 6A, FIG. 7A, FIG. 8A, FIG. 9A, FIG. 10A, FIG. 11A, FIG. 12A, FIG. 13A, and FIG. 13B to simplify the drawings. Although only four bit lines BL and two bit line connecting members 107 are shown in FIG. 5A to FIG. 13B to simplify the drawings, actually, many more bit lines BL and bit line connecting members 107 may be patterned simultaneously.

First, as shown in FIG. 5A and FIG. 5B, the inter-layer insulating film 102 is formed on the silicon substrate 101. Then, the plurality of bit line connecting members 107 are formed on the inter-layer insulating film 102. In other words, the bit line connecting members 107 are formed above the silicon substrate 101. The bit line connecting members 107 are formed of, for example, a metal material such as tungsten (W), etc. For the bit line connecting members 107, the crossing portions 107a are formed along the second direction; and the wiring portions 107b are formed to extend toward a direction away from the memory unit M.

At this time, among the plurality of bit line connecting members 107, the bit line connecting members 107 that are far to the memory unit M have long crossing portions 107a. And the other bit line connecting members 107 that are near to the memory unit M have short crossing portions 107a. Thereby, the bit line connecting members 107 that are far to the memory unit M are formed around the other bit line connecting members 107 near to the memory unit M from three directions.

Then, the insulating film 109 is formed to cover the bit line connecting members 107. A metal film of tungsten, etc., is formed on the insulating film 109. Then, a nitride film such as a silicon nitride film, etc., is formed on the metal film. Subsequently, the metal film and the nitride film are patterned by anisotropic etching such as RIE (Reactive Ion Etching), etc. Thereby, the metal film is patterned into the bit lines BL; and the nitride film is patterned into nitride films 110 on the bit lines BL. The bit lines BL are formed to extend along the first direction. At this time, when viewed from the third direction, the bit lines BL are formed to cross the crossing portions 107a of the bit line connecting members 107. Then, an insulating film is filled between the bit lines BL and the nitride films 110. If necessary, planarization is performed by CMP using the nitride films 110 as a stopper. The insulating film that is filled between the bit lines BL and the nitride films 110 also becomes a portion of the insulating film 109.

The nitride films 110 may not be formed in the case where it is unnecessary to use the nitride films 110 as a mask in the etching process performed subsequently.

FIG. 6A is a plan view of the bit line contact region showing a manufacturing process of the memory device according to the embodiment; and FIG. 6B is a cross-sectional view along line D-D′ shown in FIG. 6A.

Then, as shown in FIG. 6A and FIG. 6B, a mask material MS is formed on the insulating film 109. Multiple openings 111a are made in the mask material MS by, for example, dry etching. The configuration of each of the openings 111a is, for example, a rectangle; and etching of the front layer surfaces of the insulating film 109 and the nitride films 110 is performed. When all of the bit lines BL drawn out to the bit line contact region BPa from one bit line layer are organized into the multiple sets pBL for every two mutually-adjacent bit lines BL and the sets pBL are caused to correspond one-to-one with the bit line connecting members 107, the opening 111a is made in a region that includes, when viewed from the third direction, the space between the two bit lines BL belonging to the set pBL and the crossing region between the one bit line connecting member 107 corresponding to the set pBL.

FIG. 7A is a plan view of the bit line contact region showing a manufacturing process of the memory device according to the embodiment; and FIG. 7B is a cross-sectional view along line E-E′ shown in FIG. 7A.

Then, as shown in FIG. 7A and FIG. 7B, the insulating film 109 in the region directly under the openings 111a is selectively removed by performing RIE using the mask material MS and the nitride films 110 as a mask. Thereby, openings 111b are made in the insulating film 109. The openings 111b reach the upper surfaces of the bit line connecting members 107.

FIG. 8A is a plan view of the bit line contact region showing a manufacturing process of the memory device according to the embodiment; and FIG. 8B is a cross-sectional view along line F-F′ shown in FIG. 8A.

Then, as shown in FIG. 8A and FIG. 8B, after removing the mask material MS, the portions of the bit line connecting members 107 exposed inside the openings 111b are removed by RIE using the nitride films 110 and the insulating film 109 as a mask. Thereby, the bit line connecting members 107 are cut; and the openings 111b reach the upper surface of the inter-layer insulating film 102. At this time, the cut surfaces of the bit line connecting members 107 become the cross-sections CA. Also, when viewed from the third direction, the bit line connecting members 107 that have cut crossing portions 107a and are formed on the word line contact region WPa side become the bit line one-side connecting members 107c; and the bit line connecting members 107 that have cut crossing portions 107a and are formed on the word line contact region WPb side become the bit line one-side connecting members 107d.

FIG. 9A is a plan view of the bit line contact region showing a manufacturing process of the memory device according to the embodiment; and FIG. 9B is a cross-sectional view along line G-G′ shown in FIG. 9A.

Then, as shown in FIG. 9A and FIG. 9B, a conductive film 112 that is made of a metal material such as tungsten, titanium nitride (TiN), etc., is deposited on the entire surface of the element by sputtering. Thereby, the inner surfaces of the openings 111b made in the previous process also are covered with the conductive film 112.

FIG. 10A is a plan view of the bit line contact region showing a manufacturing process of the memory device according to the embodiment; and FIG. 10B is a cross-sectional view along line H-H′ shown in FIG. 10A.

Then, as shown in FIG. 10A and FIG. 10B, etching of the entire surface is performed so that the conductive film 112 remains on the side surfaces of the openings 111b. Thereby, the conductive film 112 remains around the side surfaces of the openings 111b.

FIG. 11A is a plan view of the bit line contact region showing a manufacturing process of the memory device according to the embodiment; and FIG. 11B is a cross-sectional view along line I-I′ shown in FIG. 11A.

Then, as shown in FIG. 11A and FIG. 11B, a resist pattern RP is formed on the element upper surface. The resist pattern RP is formed to expose the portions of the conductive film 112 connecting the two bit lines BL. At this time, the resist pattern RP is formed to partially cover the portions contacting the side surfaces of the bit lines BL.

FIG. 12A is a plan view of the bit line contact region showing a manufacturing process of the memory device according to the embodiment; and FIG. 12B is a cross-sectional view along line J-J′ shown in FIG. 12A.

Then, as shown in FIG. 12A and FIG. 12B, the portions of the conductive film 112 connecting the two bit lines BL are removed by performing isotropic etching using the resist pattern RP as a mask. At this time, the remaining conductive film 112 becomes the vias 108. Thereby, the bit lines BL that are adjacent to each other are connected respectively to the bit line connecting members 107 by the vias 108 in a state of being electrically isolated.

Continuing, the various wiring line layers and/or circuit elements are formed using general methods for manufacturing. Thus, the memory device 100 is manufactured.

Effects of the embodiment will now be described.

According to the embodiment, the via connectors of the bit lines BL or the word lines WL drawn out from the memory unit M are formed in a line-and-space configuration. Thereby, the lithography margin increases because it is unnecessary to separately form the via connectors in a configuration other than line-and-space.

Also, the vias 108 can be formed self-aligningly in the bit line contact regions BPa and BPb without alignment shift between the bit lines BL and the bit line connecting members 107.

Similarly, the vias 108 can be formed self-aligningly in the word line contact region WPa and the word line contact region WPb without alignment shift between the word lines WL and the word line connecting members 106.

A modification of the embodiment will now be described.

The configuration of the memory device according to the modification is similar to that of the embodiment.

A method for manufacturing the memory device according to the modification will now be described.

FIG. 13A and FIG. 13B are plan views of the bit line contact region showing a manufacturing process of the memory device according to the modification of the embodiment.

First, the processes shown in FIG. 5A to FIG. 10B are performed similarly to the embodiment.

Then, as shown in FIG. 13A, the resist pattern RP is formed in the element upper surface to expose only one side of the portion of the conductive film 112 linking the two bit lines BL. Then, the portion of the conductive film 112 not covered with the resist pattern RP is removed. Subsequently, the remaining resist pattern RP is removed.

Then, as shown in FIG. 13B, the resist pattern RP is formed to expose the other portions of the conductive film 112 linking the two bit lines BL. At this time, the resist pattern RP is formed to cover the portions of the conductive film 112 contacting the side surfaces of the bit lines BL. Then, the portions of the conductive film 112 not covered with the resist pattern RP are removed by etching. Subsequently, the remaining resist pattern RP is removed.

The memory device according to the modification is manufactured by the processes described above.

Effects of the memory device according to the modification will now be described.

In the memory device according to the modification, the resist pattern RP can be formed easily by dividing the etching of the conductive film 112 into two etching processes. Thereby, the degree of difficulty of the manufacturing processes of the memory device can be reduced.

According to the embodiments described above, a memory device having a higher patterning margin and a method for manufacturing the memory device can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A memory device, comprising:
a first wiring line extending in a first direction;
a second wiring line extending in a first direction, the first wiring line and the second wiring line being separated from each other;
a third wiring line separated from the first wiring line and the second wiring line, at least one portion of the third wiring line extending in a second direction crossing the first direction;
a fourth wiring line separated from the first wiring line and the second wiring line, at least one portion of the fourth wiring line extending in the second direction;
a first interconnect connected between a side surface of the first wiring line and a side surface of the third wiring line; and
a second interconnect connected between a side surface of the second wiring line and a side surface of the fourth wiring line.

2. The memory device according to claim 1, wherein the third wiring line and the fourth wiring line are located on an extension of each other.

3. The memory device according to claim 1, wherein the first wiring line and the second wiring line are arranged adjacently each other.

4. The memory device according to claim 1, wherein a distance between the side surfaces of the third wiring line and the side surfaces of the fourth wiring line is not more than the shortest distance between the first wiring line and the second wiring line.

5. The memory device according to claim 1, wherein
the third wiring line includes:
a first crossing portion extending in the second direction and passing through a region directly under the first wiring line; and
a first wiring portion extending in the first direction;
the fourth wiring line includes:
a second crossing portion extending in the second direction and passing through a region directly under the second wiring line; and
a second wiring portion extending in the first direction.

6. A memory device, comprising:
a substrate;
a first wiring line layer being disposed above the substrate, the first wiring line layer including:
a first wiring line extending in a first direction; and
a second wiring line extending in the first direction, the first wiring line and the second wiring line being separated from each other;
a second wiring line layer including:
a third wiring line, at least one portion of the third wiring line extending in a second direction crossing the first direction; and
a fourth wiring line, at least one portion of the fourth wiring line extending in the second direction;
a third wiring line layer being disposed above the first wiring line layer, the third wiring line layer including:
a fifth wiring line extending in the second direction; and
a sixth wiring line extending in the second direction, the fifth wiring line and the sixth wiring line being separated from each other;
a first memory element connected between the first wiring line and the fifth wiring line;
a second memory element connected between the first wiring line and the sixth wiring line;
a third memory element connected between the second wiring line and the fifth wiring line;
a fourth memory element connected between the second wiring line and the sixth wiring line;
a first interconnect connected between a side surface of the first wiring line and a side surface of the third wiring line; and
a second interconnect connected between a side surface of the second wiring line and a side surface of the fourth wiring line.

7. The memory device according to claim 6, wherein the third wiring line and the fourth wiring line are located on an extension of each other.

8. The memory device according to claim 6, wherein the first wiring line and the second wiring line are arranged adjacently each other.

9. The memory device according to claim 6, wherein a distance between the side surfaces of the third wiring line and the side surfaces of the fourth wiring line is not more than the shortest distance between the first wiring line and the second wiring line.

10. The memory device according to claim 6, wherein
the third wiring line includes:
a first crossing portion extending in the second direction and passing through a region directly under the first wiring line; and
a first wiring portion extending in the first direction away from the first to fourth memory elements;
the fourth wiring line includes:
a second crossing portion extending in the second direction and passing through a region directly under the second wiring line; and
a second wiring portion extending in the first direction away from the first to fourth memory elements.

11. The memory device according to claim 6, further comprising a silicon nitride film provided on the first wiring line, the second wiring line, the fifth wiring line, and the sixth wiring line.

12. The memory device according to claim 6, wherein the second wiring line layer further includes:
a seventh wiring line separated from the third wiring line and the fourth wiring line, at least one portion of the seventh wiring line extending in the first direction;
an eighth wiring line separated from the third wiring line and the fourth wiring line, at least one portion of the eighth wiring line extending in the first direction;
a third interconnect connected between a side surface of the fifth wiring line and a side surface of the seventh wiring line; and
a fourth interconnect connected between a side surface of the sixth wiring line and a side surface of the eighth wiring line.

13. The memory device according to claim 12, wherein a distance between the side surfaces of the seventh wiring line and the side surfaces of the eighth wiring line is not more than the shortest distance between the fifth wiring line and the sixth wiring line.

14. The memory device according to claim 12, wherein the second wiring line layer is disposed between the substrate and the first wiring line layer.

15. A method for manufacturing a memory device, comprising:
forming an inter-layer insulating film on a substrate;
forming a first wiring line on the inter-layer insulating film, at least one portion of the first wiring line extending in a first direction;
forming an insulating film on the first wiring line;
forming a second wiring line and a third wiring line in an upper layer portion of the insulating film, the second wiring line and the third wiring line extending in a second direction crossing the first direction;
making an opening in a portion of the insulating film including a region directly above the first wiring line between the second wiring line and the third wiring line;
separating the first wiring line into two portions by removing a portion of the first wiring line positioned at a region directly under the opening;
forming a conductive film on a side surface of the opening to contact a side surface of the second wiring line, a side surface of the third wiring line, and a pair of separated mutually-opposed side surfaces of the first wiring line; and
separating the conductive film into a portion contacting the second wiring line and a portion contacting the third wiring line by removing a portion of the conductive film.

16. The method for manufacturing the memory device according to claim 15, wherein
the making of the opening includes:
forming a mask material on the insulating film, an opening being made in the mask material in a region including a region where the first wiring line and a portion between the second wiring line and the third wiring line overlap as viewed from a direction perpendicular to the upper surface of the substrate; and
performing etching using the mask material, the second wiring line, and the third wiring line as a mask.

17. The method for manufacturing the memory device according to claim 15, wherein
the separating of the conductive film includes:
forming a mask pattern on the insulating film to cover the first-direction central portion of the opening and leave two first-direction end portions of the opening exposed; and
removing portions of the conductive film formed on side surfaces of the two end portions of the opening by performing etching using the mask pattern as a mask.
